(19) United States
(12) Patent Application Publication
(10) Pub. No.: US 2024/0372312 A1
(43) Pub. Date: Nov. 7, 2024

(54) LASER PHASE NOISE CONTROL SYSTEMS AND METHODS

(71) Applicant: Quantinuum LLC, Broomfield, CO (US)

(72) Inventors: Bruce Tiemann, Longmont, CO (US); Matthew BOHN, Broomfield, CO (US)

(21) Appl. No.: 18/605,129

(22) Filed: Mar. 14, 2024

Related U.S. Application Data
(60) Provisional application No. 63/499,298, filed on May 1, 2023.

(51) Int. Cl. H01S 3/13; H04B 10/556; H04B 10/64

(52) U.S. Cl. CPC H01S 3/1307; H04B 10/5561; H04B 10/64

(57) ABSTRACT

A multi-frequency laser system including a first beam splitter configured to split the first beam into a high-power portion of the first beam and a low power portion of the first beam and a second beam splitter configured to split the second beam into a high-power portion of the second beam and a low power portion of the second beam, wherein a frequency of the first beam is shifted with respect to a frequency of the second beam. The system includes a combiner configured to combine the low power portion of the first beam and the low power portion of the second beam to generate a heterodyne beam used to reduce a phase error between the high-power portion of the first beam and the high-power portion of the second beam.

### CROSS-REFERENCE TO RELATED APPLICATIONS

This application claims priority to U.S. Application No. 63/499,298, filed May 1, 2023, the content of which is incorporated herein by reference in its entirety.

### TECHNICAL FIELD

Various embodiments relate to a laser system. Various embodiments relate to a laser system with phase control between two or more laser sources.

### BACKGROUND

In various applications, such as coherent heterodyne optical systems and/or various optical systems used in quantum systems, optical communications, optical signal processing, optical detection, light detection and ranging systems, optical coherent tomography, etc., it may be desired to provide laser beams at particular frequencies and/or groups of laser beams having particular frequency separations and/or phase relationships. For example, quantum charge-coupled device (QCCD)-based quantum computing uses laser beams to complete various functions within the quantum computer. For example, the logic gates of the quantum computer may be implemented using laser beams.

Such applications require that the lasers are delivered precisely and accurately in terms of frequency and/or phase. Undesirable noise and/or variation in frequency and/or phase may result to the noise present in quantum computations performed by the quantum computer. Through applied effort, ingenuity, and innovation, many of these identified problems have been solved by developing solutions that are included in embodiments of the present disclosure, many examples of which are described in detail herein.

### BRIEF SUMMARY OF EXAMPLE EMBODIMENTS

Various embodiments of the present disclosure provide a laser system. In various embodiments, the laser system includes a first beam splitter configured to split a first beam into a high-power portion of the first beam and a low power portion of the first beam a second beam splitter configured to split a second beam into a high-power portion of the second beam and a low power portion of the second beam, wherein a frequency of the first beam is shifted with respect to a frequency of the second beam and an electro-optical modulator configured to generate a sideband of the low power portion of the first beam at an offset frequency from the frequency of the low power portion of the second beam, wherein a phase noise between the sideband of the low power portion of the first beam and the low power portion of the second beam is used to reduce a phase error between the high-power portion of the first beam and the high-power portion of the second beam.

In various embodiments, the offset frequency between the sideband of the low power portion of the first beam and the low power portion of the second beam is less than a frequency difference between the first beam and the second beam. In various embodiments, the laser system comprising an oscillator configured to generate an oscillation signal having an oscillation frequency equal to a frequency difference between the frequency of the low power portion of the first beam and the sideband of the low power portion of the first beam, wherein the electro-optical modulator is configured to use the oscillation signal to generate the sideband of the low power portion of the first beam.

In various embodiments, the oscillator comprising a first signal generator configured to generate a first signal generator output wherein a frequency of the first signal generator output is equal to the offset frequency; a high-frequency oscillator configured to generate a high-frequency signal output having a high frequency related to half of the shift between the frequency of the first beam with respect to the frequency of the second beam; and a first mixer configured to mix the first signal generator output with the high-frequency signal output to generate the oscillation signal.

In various embodiments, the laser system comprising a combiner configured to combine the sideband of the low power portion of the first beam and the low power portion of the second beam to generate a heterodyne beam, wherein a heterodyne frequency of the heterodyne beam is indicative of the phase noise between the sideband of the low power portion of the first beam and the low power portion of the second beam.

In various embodiments, the laser system comprising a photodetector configured to detect the heterodyne beam; and generate a detected heterodyne signal using the detection of the heterodyne beam, wherein the detected heterodyne signal comprises the phase noise between the sideband of the low power portion of the first beam and the low power portion of the second beam; and a detection phase noise generated by the photodetector in detecting the heterodyne beam.

In various embodiments, the laser system comprising a phase lock loop configured to suppress the detection phase noise in the detected heterodyne signal to generate a quiet detected heterodyne signal on an output of the photodetector, wherein the quiet detected heterodyne signal comprises the phase noise between the sideband of the low power portion of the first beam and the low power portion of the second beam. In various embodiments, the laser system comprising a second signal generator configured to generate a second signal generator output wherein a frequency of the second signal generator output is equal to the offset frequency; and a second mixer configured to mix the detected heterodyne signal with the second signal generator output to generate an error signal indicative of the detection phase noise.

In various embodiments, the laser system comprising a servo loop filter configured to receive the error signal and generate a control signal using the error signal, wherein the control signal frequency modulates the first signal generator such that a modulated first signal generator output comprises the detection phase noise. In various embodiments, the laser the first mixer is configured to mix the modulated first signal generator output with the high-frequency signal output such that the detection phase noise in the detected heterodyne signal is suppressed and a quiet detected heterodyne signal on an output of the photodetector is generated, wherein the quiet detected heterodyne signal comprises the phase noise between the sideband of the low power portion of the first beam and the low power portion of the second beam.

In various embodiments, the laser system further comprising a third signal generator configured to generate a third signal generator output having a frequency approximately equal to the offset frequency plus a driving frequency value; a third mixer configured to mix the third signal generator output with the modulated first signal generator output to generate a third mixer output signal; an acoustic optical modulator configured to correct the phase error between the high-power portion of the first beam and the high-power portion of the second beam by modulating the high-power portion of the first beam using the third mixer output signal; and a radio frequency switch electronically coupled to the third mixer and the acoustic optical modulator, the radio frequency switch configured to switch on or off the modulation by the acoustic optical modulator using the third mixer output signal.

In various embodiments, the high-power portion of the first beam and the high-power portion of the second beam entangle qubits in a quantum computer. In various embodiments, the high-power portion of the first beam and the high-power portion of the second beam provide a first and second laser sources in a coherent heterodyne optical system. In various embodiments, the laser the coherent heterodyne optical system comprises a light detection and ranging (lidar) system. In various embodiments, the coherent heterodyne optical system comprises an optical communications system.

Various embodiments of the present disclosure provide a laser system comprising a first beam splitter configured to split the first beam into a high-power portion of the first beam and a low power portion of the first beam; a second beam splitter configured to split the second beam into a high-power portion of the second beam and a low power portion of the second beam, wherein a frequency of the first beam is shifted with respect to a frequency of the second beam; and a combiner configured to combine the low power portion of the first beam and the low power portion of the second beam to generate a heterodyne beam, wherein a heterodyne frequency of the heterodyne beam is indicative of a phase noise between the low power portion of the first beam and the low power portion of the second beam, and the phase noise between the low power portion of the first beam and the low power portion of the second beam is used to reduce a phase error between the high-power portion of the first beam and the high-power portion of the second beam.

In various embodiments, the laser system comprising a photodetector configured to: detect the heterodyne beam having the heterodyne frequency; and generate a detected heterodyne signal by detecting the heterodyne beam, wherein the detected heterodyne signal comprises the phase noise between the low power portion of the first beam and the low power portion of the second beam; and a detection phase noise generated by the photodetector in detecting the heterodyne beam; a detection phase noise reduction circuitry configured to reduce the detection phase noise in the detected heterodyne signal; and a modulator configured to correct the phase error between the high-power portion of the first beam and the high-power portion of the second beam using the detected heterodyne signal and the reduction of the detection phase noise.

In various embodiments, the laser system comprising a fourth signal generator configured to generate a fourth signal generator output, wherein the fourth signal generator is a voltage-controlled signal generator; a fourth mixer configured to mix the fourth signal generator output with a high frequency oscillator output to generate a fourth mixer output signal; a fifth mixer configured to mix the fourth mixer output signal with the detected heterodyne signal to generate a fifth mixer output signal; a fifth signal generator configured to generate a fifth signal generator output; a sixth mixer configured to mix the fifth signal generator output with the fifth mixer output signal to generate a sixth mixer output signal; a servo loop filter configured to receive the sixth mixer output signal and generate a control signal using the sixth mixer output signal, wherein the control signal frequency modulates the fourth signal generator to generate a modulated fourth signal generator output; a sixth signal generator configured to generate a sixth signal generator output; a seventh mixer configured to mix the modulated fourth signal generator output with the sixth signal generator output to generate a seventh mixer output signal; a first acoustic optical modulator configured to correct the phase error between the high-power portion of the first beam and the high-power portion of the second beam by modulating the high-power portion of the first beam using the seventh mixer output signal or a second acoustic optical modulator configured to correct the phase error between the high-power portion of the first beam and the high-power portion of the second beam by modulating the high-power portion of the second beam using the seventh mixer output signal; and a radio frequency switch electronically coupled to the seventh mixer and the acoustic optical modulator, the radio frequency switch configured to switch on or off the modulation by the acoustic optical modulator using the seventh mixer output signal.

In various embodiments, the laser system comprising a fifth signal generator configured to generate a fifth signal generator output; a fourth mixer configured to mix the fifth signal generator output with an output of a high-frequency oscillator to generate a fourth mixer output signal; a fifth mixer configured to mix the fourth mixer output signal with the detected heterodyne signal to generate a fifth mixer output signal; a sixth signal generator configured to generate a sixth signal generator output; a seventh mixer configured to mix the fifth mixer output signal with the sixth signal generator output to generate a seventh mixer output signal; a first acoustic optical modulator configured to correct the phase error between the high-power portion of the first beam and the high-power portion of the second beam by modulating the high-power portion of the first beam using the seventh mixer output signal or a second acoustic optical modulator configured to correct the phase error between the high-power portion of the first beam and the high-power portion of the second beam by modulating the high-power portion of the second beam using the seventh mixer output signal; and a radio frequency switch electronically coupled to the seventh mixer and the acoustic optical modulator, the radio frequency switch configured to switch on or off the modulation by the acoustic optical modulator using the seventh mixer output signal.

In various embodiments, the high-power portion of the first beam and the high-power portion of the second beam entangle qubits in a quantum computer. In various embodiments, the high-power portion of the first beam and the high-power portion of the second beam provide a first and second laser sources in a coherent heterodyne optical system. In various embodiments, the coherent heterodyne optical system comprises any of an optical communications system or a light detection and ranging (lidar) system.

Various embodiments of the present disclosure provide a method for reducing phase noise between optical beams. In various embodiments, the method comprises splitting a first beam into a high-power portion of the first beam and a low power portion of the first beam; splitting a second beam into a high-power portion of the second beam and a low power portion of the second beam, wherein a frequency of the first beam is shifted with respect to a frequency of the second beam; generating a sideband of the low power portion of the first beam at an offset frequency from the frequency of the low power portion of the second beam; and reducing the phase error between the high-power portion of the first beam and the high-power portion of the second beam using a phase noise between the sideband of the low power portion of the first beam and the low power portion of the second beam.

The foregoing illustrative summary, as well as other exemplary objectives and/or advantages of the disclosure, and the manner in which the same are accomplished, are further explained in the following detailed description and its accompanying drawings.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is a schematic diagram illustrating various aspects of a bichromatic laser system in accordance with various embodiments of the present disclosure;

FIG. 2 is a schematic diagram illustrating various aspects of a trapped quantum object quantum computer system in accordance with various embodiments of the present disclosure;

FIG. 3 is a schematic diagram illustrating various aspects of a laser system in accordance with various embodiments of the present disclosure;

FIG. 4 is a schematic diagram illustrating a frequency diagram in accordance with various embodiments of the present disclosure;

FIG. 5 is a schematic diagram illustrating various aspects of a laser system in accordance with various embodiments of the present disclosure;

FIG. 6 is a schematic diagram illustrating various aspects of a laser system in accordance with various embodiments of the present disclosure;

FIG. 7 is a flow chart illustrating various steps of a method in accordance with various embodiments of the present disclosure;

FIG. 8 is a schematic diagram illustrating various aspects of a laser system in accordance with various embodiments of the present disclosure;

FIG. 9 is a schematic diagram illustrating various aspects of a laser system in accordance with various embodiments of the present disclosure;

FIG. 10 is a schematic diagram illustrating various aspects of a laser system in accordance with various embodiments of the present disclosure;

FIG. 11 is a schematic diagram illustrating various aspects of a controller in accordance with various embodiments of the present disclosure; and

FIG. 12 is a schematic diagram illustrating various aspects of a computing entity in accordance with various embodiments of the present disclosure.

### DETAILED DESCRIPTION OF SOME EXAMPLE EMBODIMENTS

The present invention now will be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally” and “approximately” refer to within engineering and/or manufacturing limits and/or within user measurement capabilities, unless otherwise indicated. Like numbers refer to like elements throughout. The term “beam” may refer to any optical, laser, and/or ultraviolet (UV) beams. The term “signal” may refer to any of a radio frequency (RF), microwave, or direct current (DC) signals. The term “electronically coupled” in the present disclosure refers to two or more electrical components (for example, but not limited to, a controller, a signal generator, a mixer, an oscillator, a switch, a modulator, a servo, a detector, etc.) and/or electric circuit(s) being connected through wired means (for example but not limited to, conductive wires or traces) and/or wireless means (for example but not limited to, wireless network, electromagnetic field), such that data and/or information (for example, electronic indications, signals) may be transmitted to and/or received from the electrical components and/or electric circuit(s) that are electronically coupled.

As described above, in various optical systems, it is important to be able to deliver one or more laser beams precisely and accurately, in terms of, for example, frequency and/or phase. In an example of a quantum system, such as quantum clocks, Bose-Einstein condensate systems, trapped quantum object systems, QCCD-based quantum computers, and/or other quantum computing systems, precise and accurate laser beam delivery is important for various uses of the system, manipulating the system, and/or the like such as described in the U.S. Pat. No. 10,951,002 B1 issued Mar. 16, 2021, which is incorporated herein by reference in its entirety.

### Example Bichromatic Laser System

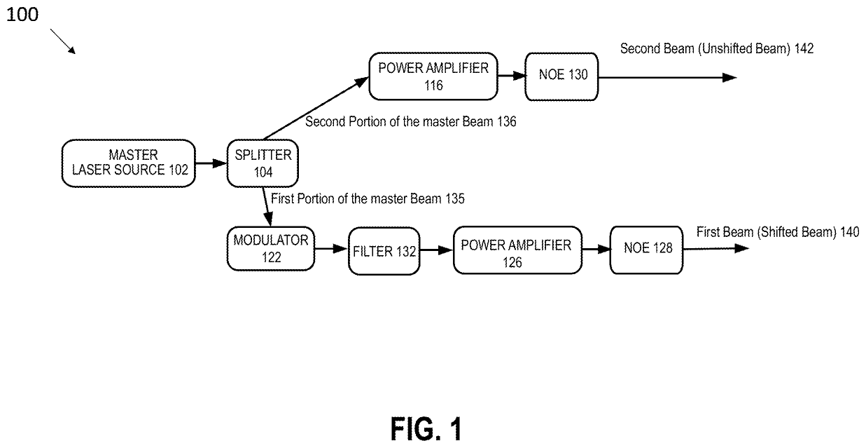

Referring now to FIG. 1 a schematic diagram illustrating various aspects of a bichromatic laser system 100 is provided in accordance with various embodiments of the present disclosure. In various embodiments, the bichromatic laser system 100 includes a master laser source 102. In various embodiments, the master laser source 102 is a laser source coupled to a resonance chamber (e.g., reference cavity and/or the like)_and/or any other laser oscillator. In an example embodiment, the master laser source 102 is a diode laser coupled to a tapered amplifier. In an example embodiment, the master laser source 102 is a low phase noise laser.

In various embodiments, the master laser source 102 is optically coupled to a splitter 104. In various embodiments, a master beam generated by the master laser source 102 is provided to the splitter 104 e.g., via an optical fiber, waveguide, free space optical path, and/or the like. The splitter 104 may be configured to split the master beam into two or more beams. In an example embodiment, the arm splitter 104 is a 1×2 splitter and is configured to split the master beam provided by the master laser source 102 into two beams for example a first portion of the master beam 135 and a second portion of the master beam 136. In an example embodiment, the arm splitter 104 is configured to split the master beam provided by the master laser source 102 into two beams of approximately the same intensity.

In various embodiments, the first portion of the master beam is transmitted from the splitter 104 to a modulator 122. For example, the first portion of the master beam may be transmitted from the splitter 104 to the modulator 122 via an optical fiber, waveguide, free space optical path, and/or the like. In an example embodiment, the modulator 122 is a fiber or waveguide electro-optical modulator, though a variety of modulators may be used in various embodiments. In various embodiments, the modulator 122 is configured to phase modulate the first portion of the master beam. The phase modulation of the first portion of the master beam (e.g., by the modulator 122) may generate a beam comprising plurality of sidebands that have a shifted frequency and/or phase with respect to the first portion of the master beam. In various embodiments, a sideband is a band of frequencies higher or lower than the frequency of the first portion of the master beam from which the beam comprising a plurality of sidebands was generated.

In an example embodiment, the modulator 122 phase modulates the first portion of the master beam at a frequency of Δ/2, where Δ is the relative frequency difference between a shifted beam 140 (e.g. a frequency shifted beam with respect to the master beam) and an unshifted beam 142 (e.g. unshifted in frequency with respect to the master beam). For example, one of the sideband modes may have a peak frequency that is shifted frequency with respect to the first portion of the master beam (and/or a second portion of the master beam and/or the master beam and/or the primary beam) by approximately half of the relative frequency difference Δ between the shifted beam 140 and the unshifted beam 142.

The beam comprising the plurality of sidebands may then be provided (e.g., via optical fiber, waveguide, free space optical path, and/or the like) to a power amplifier 126. In various embodiments, the power amplifier 126 is configured to amplify and/or increase the intensity of the beam comprising the plurality of sidebands. The output of the power amplifier 126 is then be provided to a filter 132. In various embodiments, the filter 132 is a narrow band filter configured to select the desired sideband from the amplified beam comprising the plurality of sidebands. In an example embodiment, the filter 132 is an etalon (e.g., a near infrared etalon). An etalon may be a device comprising of two reflecting glass plates that may be used for selection of light of a particular frequency (e.g., based on the distance between the two glass plates). In example embodiments, the filter 132 may be various other types of filters, as appropriate for the application. In an example embodiment, the filter 132 suppresses the unselected sidebands to <1% of their intensity in the amplified beam comprising the plurality of sidebands. In an example embodiment, the selected sideband is a sideband having a frequency difference with respect to the first portion of the master beam (and/or second portion of master beam and/or master beam and/or primary beam) of Δ/2. In various embodiments, a selected sideband beam is provided to the power amplifier 126.

In various embodiments, the selected sideband beam is provided to the power amplifier 126 (e.g., by optical fiber, waveguide, free space optical path, and/or the like) for amplification. In various embodiments, the power amplifier 126 may act to amplify and/or increase the intensity of the selected sideband beam and to further suppress the sidebands not selected by the filter 132. In an example embodiment, the power amplifier 126 may suppress the sidebands not selected by the filter 132 by approximately −30 dB. For example, the amplified selected sideband beam may be transmitted from the power amplifier 226B (e.g., via an optical fiber, waveguide, free space optical path, and/or the like) to a nonlinear optical element (NOE) 128. In various embodiments, the NOE 128 is configured to double the frequency of the sideband beam (e.g., reduce the wavelength of the sideband beam by a factor two) to provide the shifted beam 140. In various embodiments, the frequency difference between the shifted beam 140 and the master beam is half the final relative frequency difference (e.g., Δ/2) between the shifted beam 140 and the unshifted beam 142. The frequency difference between the shifted beam 140 and the master beam is the final relative frequency difference Δ, which is the frequency difference between the shifted beam 140 and the unshifted beam 142.

In an example embodiment, the second portion of the master beam is transmitted from the splitter 104 to a power amplifier 116. For example, the second portion of the master beam may be transmitted from the splitter 104 to the power amplifier 116 via an optical fiber, waveguide, free space optical path, and/or the like. In various embodiments, the power amplifier 116 is configured to amplify and/or increase the intensity of the second portion of the master beam to generate the unshifted beam 142. In example embodiments, the amplified second portion of the master beam may be transmitted from the power amplifier 116 (e.g., via an optical fiber, waveguide, free space optical path, and/or the like) to another nonlinear optical elements (NOE) 130. In various embodiments, the NOE 130 is configured to double the frequency of the sideband beam (e.g., reduce the wavelength of the sideband beam by a factor two) to provide the unshifted beam 142.

In example embodiments, the first and the second beams may be generated using an NOE on each for each portion of the master beam or using only one NOE on one of the portions of the master beam. In example embodiments, the first and the second (shifted and unshifted) beams 140 and 142 may be generated without using an NOE.

### Example Quantum Computer System Application

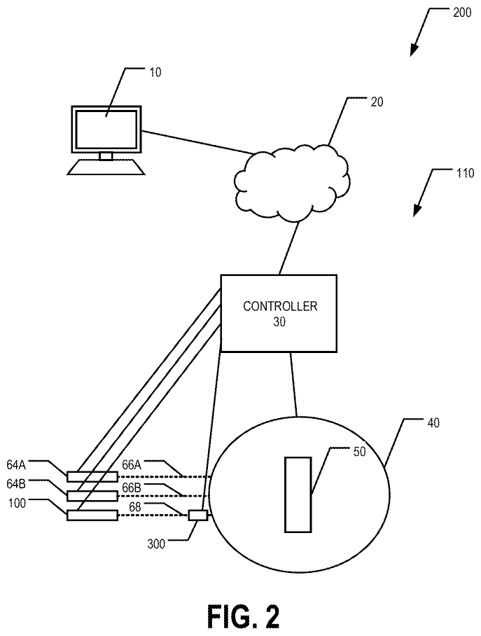

FIG. 2 provides a schematic diagram of an example trapped quantum object quantum computer system 200, in accordance with an example embodiment. In various embodiments, the quantum computer system 200 comprises a computing entity 1210 and a quantum computer 110. In various embodiments, a controller 1130 of the quantum computer 110 may be in communication with the computing entity 1210 via one or more wired and/or wireless networks 20. In various embodiments, the quantum computer 110 comprises the controller 1130, a cryo and/or vacuum chamber 40 enclosing a trap 50, one or more manipulation sources 64 (e.g., 64A, 64B), one or more bichromatic laser systems 100, and/or the like. In various embodiments, the trap 50 is configured to trap one or more quantum objects therein and the manipulation sources 64 are configured to provide manipulation signals to one or more portions of the trap 50 via optical paths 66 (e.g., 66A, 66B). In various embodiments, the manipulation signals may be used to initialize one or more quantum objects into a qubit space, perform cooling operations, perform measurement operations, and/or the like. In various embodiments, the bichromatic laser system 100 is configured to provide one or more gate signals to one or more portions of the trap 50 to enact one or more quantum gates (e.g., quantum logic gates). In various embodiments, the quantum gates may be one qubit gates, two qubit gates, and/or the like. In various embodiments, the one or more gate signals may be provided to the one or more portions of the trap 50 via optical path(s) 68. In various embodiments, the quantum objects trapped within the trap 50 are ions, atoms, and/or the like. For example, in an example embodiment, a quantum object is an ytterbium ion. In an example embodiment, a quantum object comprises a qubit ion and a corresponding cooling ion.

In various embodiments, a computing entity 1210 is configured to allow a user to provide input to the quantum computer system 200 (e.g., via a user interface of the computing entity 1210) and receive, view, and/or the like output from the quantum computer system 200. The computing entity 1210 may be in communication with the controller 1130 via one or more wired or wireless networks 20. For example, the computing entity 1210 may be configured to provide quantum circuits to the controller 1130 for execution by the quantum computer 110 and the controller 1130 may provide the results of executing one or more quantum circuits to the computing entity 1210.

In various embodiments, the controller 1130 is configured to control the trap 50, cooling and/or vacuum systems (not shown) controlling the temperature and pressure within the cryo and/or vacuum chamber 40, manipulation sources 64, bichromatic laser system 100, and/or other components of the quantum computer 110 (e.g., an optical collection system configured for “reading” the output of the quantum computer). In various embodiments, the controller 1130 is configured to control various components of the quantum computer 110 in accordance with executable instructions, command sets, and/or the like provided by the computing entity 1210 and/or generated by the controller 1130. In various embodiments, the controller 1130 is configured to receive output from the quantum computer 110 (e.g., from an optical collection system) and provide the output and/or the result of processing the output to the computing entity 1210.

In various embodiments, the bichromatic laser system 100 is configured to facilitate the entangling operation that entangles two qubits together can be of importance. For example, two qubits may be entangled together by use of a pair of laser beams, such as the shifted beam 140 and the unshifted beam 141 with reference to FIG. 1, having one or more frequency differences near the qubit transition frequency. In various embodiments, it is desirable for the two beams to have zero relative phase noise (i.e. other than the intended frequency separation(s) and/or frequency shift(s)), and there would be no other sources of error in the phase and/or frequency difference between the two beams, such that the resulting entanglement would be perfect. However, a relative phase noise between the gate laser beams may contribute to imperfect gate operation. Consequently, to reduce gate infidelity, it is desirable to reduce such relative phase noise. Various embodiments of the present disclosure provide methods, systems, and techniques to reducing the phase noise between the two laser beams such as by detecting and suppressing or mitigating the phase noise.

### Example Laser Phase Noise Reduction Systems

Various embodiments herein, as further described below, provide a laser phase noise control system for controlling of the phase of the laser beams. In various embodiments, the laser phase noise control system may include a phase noise detection system configured to detect the phase noise, and a phase noise reduction system configured to reduce the phase noise between the laser beams.

In example embodiments, 171Yb+ ion may be used as the qubit. The 171Yb+ ion has a qubit frequency of about 12.6 GHZ, necessitating a gate laser frequency separation of that value. In various embodiments, additional optical tones necessary e.g., for entanglement may be imposed on the one or more beams by subsequent optical modulators.

In example embodiments, the gate laser wavelengths in this case may be near 369 nm, and they may be generated by the frequency-doubling of light near 738 nm. In various embodiments, the efficiency of the doubling process may be enhanced by use of build-up cavities for the two beams, in which case the cavities need to be made resonant to the frequencies each is doubling. For example, Pound-Drever-Hall (PDH) frequency phase-locking may be used for such purpose. However, it may entail a phase modulation which may increase the resulting relative phase noise. Various embodiments herein provide control and reduction of the resulting relative phase noise.

For example, various embodiments herein provide for reducing the relative phase noise between the beams arising from the phase modulation used for PDH by using a common signal, for example in which the common 738 nm laser is phase modulated prior to being split into the first portion of the master beam and the second portion of the master beam. Accordingly, in various embodiments, the necessary phase modulation is common mode hence does not contribute to relative phase noise between the beams, compared to having independent modulation sources for each separate PDH system, e.g., frequency doubling build-up cavities. Additionally, in this embodiment the relative intensity noise (RIN) of the beams may be reduced.

In various embodiments, the phase difference of a first gate beam and a second gate beam is determined by interfering samples of the beams together in an interferometer, resulting in a heterodyne beam, for example a 12.6 GHz heterodyne beam for the 171Yb+ ion. In various embodiments, the phase noise of the resulting heterodyne beam is the phase noise that is desirable to suppress. In various embodiments, the heterodyne beam may be down-converted to baseband, and the resulting phase error signal used to control an optical phase modulator in at least one of the beams, thereby reducing the phase noise between the beams.

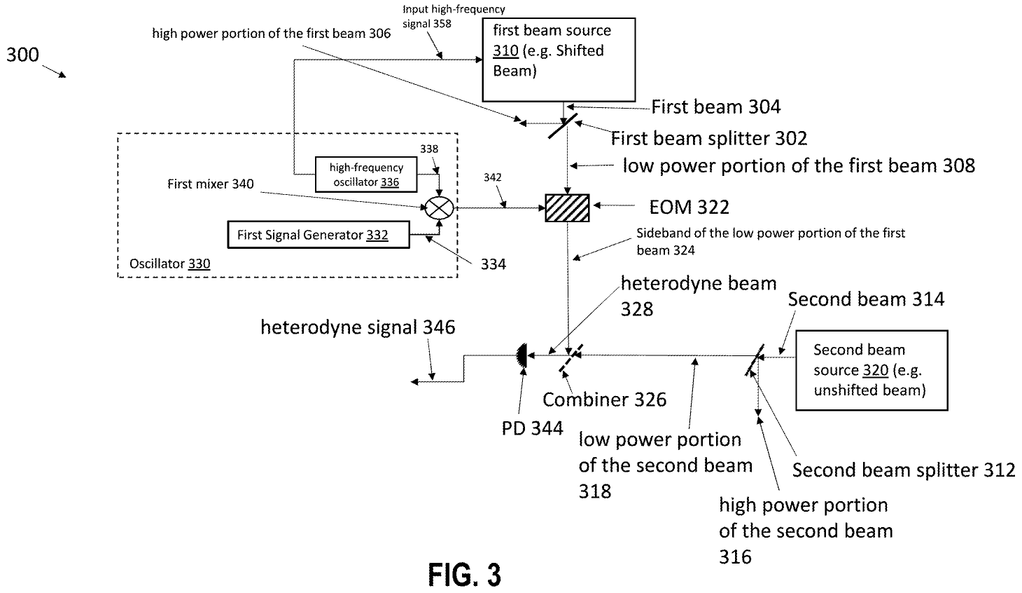

Referring now to FIG. 3 a schematic diagram illustrating various aspects of a laser system 300 is provided in accordance with various embodiments of the present disclosure. In various embodiments, the laser system 300 provides phase noise control. In various embodiments, the laser system 300 includes a first beam splitter 302 configured to split a first beam 304 into a high-power portion 306 of the first beam and a low power portion 308 of the first beam. In various embodiments, the first beam 304 is generated using the first beam source 310. For example, the first beam 304 is the shifted beam 140 with reference to FIG. 1.

In various embodiments, the bichromatic laser system 100 includes a second beam splitter 312 configured to split the second beam 314 into a high-power portion 316 of the second beam and a low power portion 318 of the second beam. In various embodiments, a frequency of the first beam 304 is shifted with respect to a frequency of the second beam 314. In various embodiments, the second beam 314 is generated using the second beam source 320. For example, the second beam 314 is the unshifted beam 142 with reference to FIG. 1. In various embodiments, frequency shifted and unshifted laser beams may be generated using various other methods and techniques.

In various embodiments, the bichromatic laser system 100 may include an electro-optical modulator (EOM) 322 configured to generate a sideband 324 of the low power portion of the first beam at an offset frequency from the frequency of the low power portion of the second beam. In various embodiments, a phase noise between the sideband of the low power portion of the first beam and the low power portion of the second beam is used to reduce a phase error between the high-power portion 306 of the first beam and the high-power portion 316 of the second beam.

In various embodiments, the offset frequency between the sideband 324 of the low power portion of the first beam and the low power portion 318 of the second beam is less than a frequency difference between the first beam and the second beam.

In various embodiments, the EOM 322 downshifts the optical phase difference between the low power portion of first and second beams into the same optical phase difference in a lower frequency. In various embodiments, the optical phase difference between the sideband 324 of the low power portion of the first beam and the low power portion 318 of the second beam is the same as the optical phase difference between the low power portion 308 of the first beam and low power portion 318 of the second beam.

In various embodiments, the laser system 300 includes a combiner 326 configured to combine the sideband 324 of the low power portion of the first beam and the low power portion 318 of the second beam to generate a heterodyne beam 328. In various embodiments, a heterodyne frequency of the heterodyne beam 328 is indicative of the phase noise between the sideband of the low power portion of the first beam and the low power portion of the second beam. In various embodiments, the heterodyne beam contains the phase noise of the frequency difference between the first and second beams. In various embodiments, the heterodyne beam contains information of the phase noise of the frequency difference between the first and second beams.

In various embodiments, the phase noise of the frequency difference between the low power portion of the first and second beams (which is equal to the phase noise of the frequency difference between the first and second beams) is determined by detecting the heterodyne signal. In example embodiments, using the low power portion of the first and second beams provides for using less optical power in the laser system 300 as used for detection of the phase noise.

In various embodiments, combining the low power portion 318 of the second beam with the sideband 324 of the of the low power portion of the first beam (which is closer in frequency band to the low power portion 318 of the second beam that the low power portion 308 of the first beam) provides a heterodyne beam at a lower frequency range. For example, using the example above, the EOM 322 may operate at and modulate the low power portion 308 of the first signal with a 12.3 GHz signal, resulting in a heterodyne beam at 300 MHZ (rather than at 12.6 GHz otherwise without modulating the lower power portion 308 of the first signal with the EOM in this example). In example embodiments, the heterodyne beam may be in a range of 100 MHz to 500 MHz. In example embodiments, the heterodyne beam may be in a range of 150 MHz to 400 MHz. In example embodiments, the heterodyne beam may be in a range of 200 MHz to 300 MHz. In example embodiments, the heterodyne beam may have a frequency of about 250 MHz. In example embodiments the heterodyne beam may have any other frequencies. In example embodiments, having a lower frequency for the heterodyne beam than the frequency difference between the first and second beams allows for using photodetectors with larger detection areas, hence having better detection capabilities. In example embodiments, doing so may provide more convenience in aligning the photodetector, and/or having more sensitivity in the photodetector and detecting beams that would have otherwise been harder to detect in the original, unshifted optical frequency difference. Further, in example embodiments, less laser energy may be needed for the optical phase measurement system when the detectors being used in the phase detection system are more sensitive, leaving more laser energy to be available elsewhere in the system.

In various embodiments, the EOM 322 operates at a frequency different from frequency separation of the first and second beams. In various embodiments, the laser system 300 includes an oscillator 330. In various embodiments, the oscillator 330 is configured to generate an oscillation signal 342 for the EOM 322 to operate at. In various embodiments, the EOM is configured to use the oscillation signal 342 to generate the sideband of the low power portion of the first beam. The oscillator 330 may be configured to generate an oscillation signal having an oscillation frequency different from frequency separation of the first and second beams. In various embodiments, the oscillation frequency is equal to a frequency difference between the frequency of the low power portion 308 of the first beam and the sideband 324 of the low power portion of the first beam.

In various embodiments, the oscillator 330 includes a first signal generator. The first signal generator may be configured to generate a first signal generator output signal 334. In various embodiments, a frequency of the first signal generator output is equal to the offset frequency between the sideband 324 of the low power portion of the first beam and the low power portion 318 of the second beam. In various embodiments, a frequency of the first signal generator output is equal to the frequency of the heterodyne beam 328.

In various embodiments, the oscillator 330 includes a high-frequency oscillator 336. In various embodiments, the high-frequency oscillator 336 is configured to generate an input high-frequency signal 358 to the first beam source 310. In various embodiments, the high-frequency oscillator 336 is configured to generate a high-frequency signal output 338. In various embodiments, the frequency of the input high-frequency signal 358 to the first beam source 310 is different from a frequency than the high-frequency signal output 338. For example, the frequency of the input high-frequency signal 358 to the first beam source 310 is twice the frequency than the high-frequency signal output 338.

The high-frequency signal output 338 may have a high frequency related to half of the shift between the frequency of the first beam 304 with respect to the frequency of the second beam 314. In various embodiments, the oscillator 330 includes a first mixer 340 configured to mix the first signal generator output 334 with the high-frequency signal output 338 to generate the oscillation signal 342.

In various embodiments, the laser system 300 includes a photodetector (PD) 344 configured to detect the heterodyne beam 328. In various embodiments, the PD 344 generates a detected heterodyne signal 346 using the detection of the heterodyne beam. In various embodiments, the detected heterodyne signal comprises the phase noise between the sideband of the low power portion of the first beam and the low power portion of the second beam, and a detection phase noise generated by the photodetector in detecting the heterodyne beam. In various embodiments, the detected heterodyne signal comprises information of the phase noise between the sideband of the low power portion of the first beam and the low power portion of the second beam, and information of the detection phase noise generated by the photodetector in detecting the heterodyne beam.

In example embodiments, the phase noise between the sideband of the low power portion of the first beam and the low power portion of the second beam is an indication of the phase noise between the first and second beams. In example embodiments, it is desired to detect the phase noise between the sideband of the low power portion of the first beam and the low power portion of the second beam and use it for correcting the frequency and/or phase of the first or second beams to reduce and/or remove the phase noise between the first and second beams. In example embodiments, the detection phase noise is a byproduct of the operation of the photodetector and is not an indicative of the phase noise between the first and second beams. In various embodiments, the detection phase noise generated by the photodetector is suppressed.

In various embodiments, one or more folding mirrors may be used between the component for flexibility is arranging the components and/or reducing the overall footprint of the laser system. In various embodiments, the beams in the laser system are provided to various components and or transmitted between various components using any of optical fiber, waveguide, free space optical path, and/or the like.

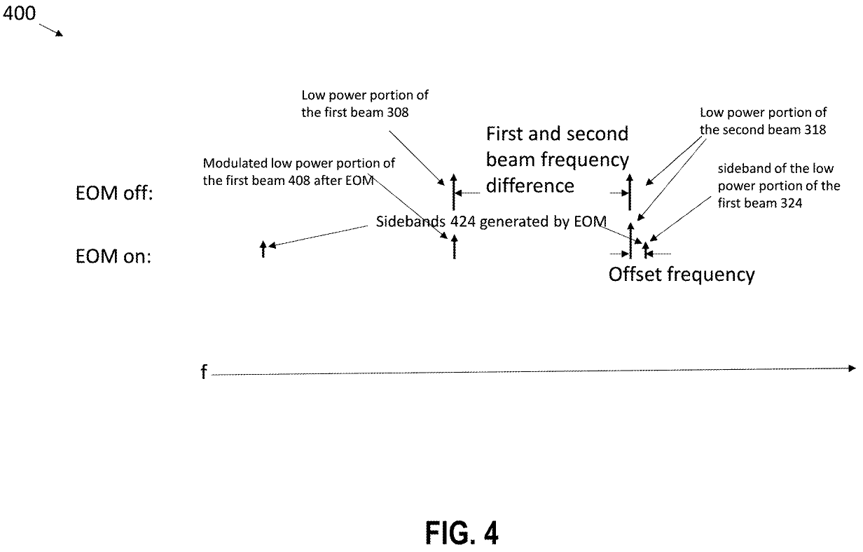

Referring now to FIG. 4 a schematic diagram illustrating a diagram 400 is provided in accordance with various embodiments of the present disclosure. In various embodiments, the EOM modulates the low power portion 308 of the first beam. In various embodiments, the EOM generates the modulated low power portion 408 of the first beam including the sidebands 424 when the EOM is on and modulates the low power portion 308 of the first beam.

In various embodiments, the sideband 324 of the low power portion of the first beam has the offset frequency from the frequency of the low power portion 318 of the second beam. In various embodiments, the sideband 324 of the low power portion of the first beam is combined with the low power portion 318 of the second beam to generate the heterodyne beam.

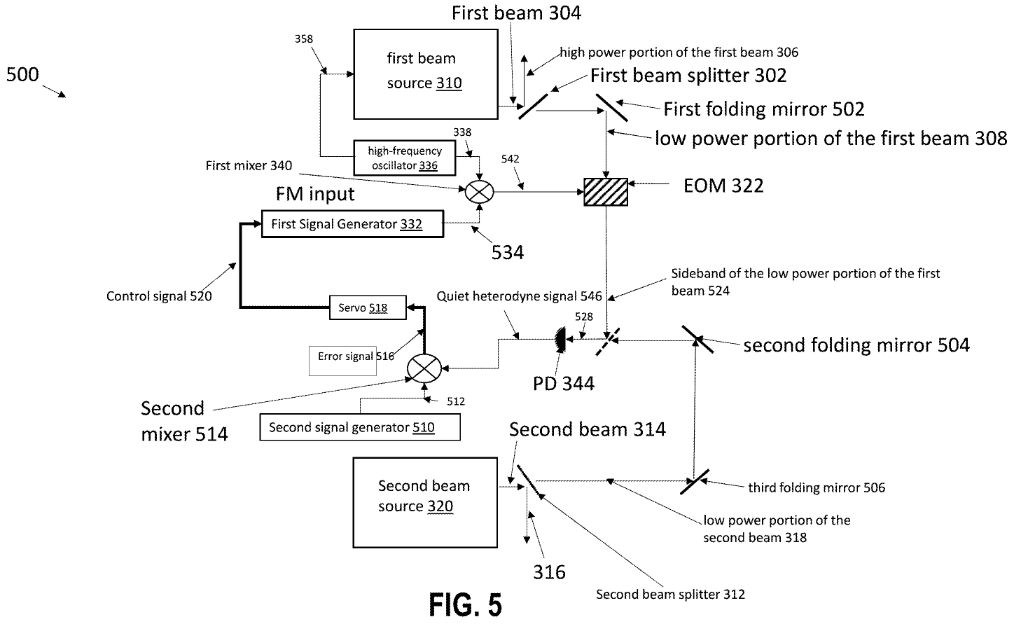

Referring now to FIG. 5 a schematic diagram illustrating various aspects of a laser system 500 is provided in accordance with various embodiments of the present disclosure. In various embodiments, the laser system 500 suppresses the detection phase noise generated by the photodetector on the heterodyne signal.

In various embodiments, the laser systems herein may include a folding mirror 502 to redirect the low power portion 308 of the first beam. In various embodiments, the laser systems herein may include any of the folding mirrors 504 and/or 506 to redirect the low power portion of the second beam. In various embodiments, the laser systems herein may include any other and/or any other number(s) and/or arrangement(s) of the folding mirror(s) and/or any other redirecting component(s) such as prisms, etc., to redirect any of the beams. In various embodiments, the laser systems herein may use any of optical fibers, waveguides, etc., to route and/or redirect the beams. In various embodiments, redirecting and/or routing the beams may be used for flexibility and/or optimizing the placement or arrangement of the components of the system. In various embodiments, the laser systems herein may not use folding mirror(s) and/or redirecting component(s).

In various embodiments, the laser system 500 incudes a second signal generator 510. In various embodiments, the second signal generator 510 is configured to generate a second signal generator output 512. In various embodiments, a frequency of the second signal generator output is equal to the offset frequency between the sideband 324 of the low power portion of the first beam and the low power portion 318 of the second beam.

In various embodiments, the laser system 500 includes a second mixer 514. The second mixer 514 may be configured to mix the detected heterodyne signal 346 with the second signal generator output 512 to generate an error signal 516. In various embodiments, the error signal 516 is indicative of the detection phase noise. In various embodiments, the laser systems herein suppress the detection phase noise.

In various embodiments, the laser system 500 includes a servo 518. In various embodiments, the servo 518 is a servo loop filter. In various embodiments, the servo 518 is configured to receive the error signal 516 and generate a control signal 1220 using the error signal. In various embodiments, the control signal 1220 frequency modulates the first signal generator 332 such that a modulated first signal generator output 534 comprises the detection phase noise.

In various embodiments, the first mixer 340 is configured to mix the modulated first signal generator output 534 with the high-frequency signal output 338 such that the detection phase noise in the detected heterodyne signal is suppressed and a quiet detected heterodyne signal 546 on an output of the photodetector is generated. In various embodiments, the quiet detected heterodyne signal 546 comprises the phase noise between the sideband of the low power portion of the first beam and the low power portion of the second beam.

In various embodiments, mixing the modulated first signal generator output 534 with the high-frequency signal output 338 to generate the modulated oscillation signal 542.

In various embodiments, the oscillator 330 in the laser system 500 is configured to generate the modulated oscillation signal 542 for the EOM 322 to operate at. In various embodiments, in the laser system 500, the EOM 322 operates at the frequency of the modulated oscillation signal 542. In various embodiments, the EOM is configured to use the oscillation signal 542 to generate a modulated sideband 524 of the low power portion of the first beam. By combining the modulated sideband 524 of the low power portion of the first beam with the low power portion 318 of the second beam, a modulated heterodyne beam 528 is generated. By detecting the modulated heterodyne beam 528 by the photodetector 344, the output of the photodetector 344 changes from the heterodyne signal 346 (with reference to FIG. 3) to the quiet heterodyne signal 546 in the laser system 500.

In various embodiments, a phase lock loop is used to suppress the detection phase noise. In various embodiments, the phase lock loop is configured to suppress the detection phase noise in the detected heterodyne signal to generate a quiet detected heterodyne signal on an output of the photodetector. In various embodiments, the quiet detected heterodyne signal includes the phase noise between the sideband of the low power portion of the first beam and the low power portion of the second beam. In various embodiments, the quiet detected heterodyne signal includes information of the phase noise between the sideband of the low power portion of the first beam and the low power portion of the second beam. In various embodiments, the phase lock loop includes any of the first and/or second signal generator(s), first and/or second mixer(s), servo, EOM, combiner, and/or photodetector as for example illustrated with reference to FIG. 5. In various embodiments, a phase lock loop having other components and/or arrangements may be used.

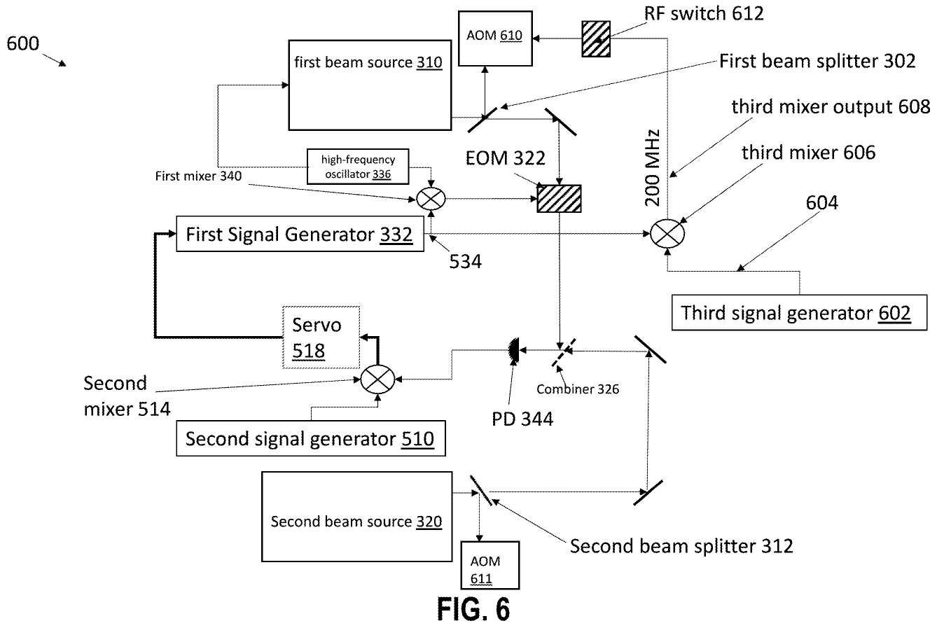

Referring now to FIG. 6 a schematic diagram illustrating various aspects of a laser system 600 is provided in accordance with various embodiments of the present disclosure. In various embodiments, the laser system 600 includes a third signal generator 602. In example embodiments, the third signal generator 602 may be configured to generate a third signal generator output 604 having a frequency approximately equal to the offset frequency plus a driving frequency value. In various embodiments, the driving frequency value is a driving frequency for an acoustic optical modulator configured to correct the phase error between the high-power portion of the first beam and the high-power portion of the second beam. In example embodiments, the driving frequency value is a preferred driving frequency for the acoustic optical modulator.

In example embodiments, the driving frequency value may be in any of 20 MHz-1 GHZ, 30 MHz-500 MHz, 50 MHz-400 MHZ, 100-300 MHz. In example embodiments, the driving frequency may be approximately 150 MHz. In example embodiments, the driving frequency may be approximately 200 MHz. In example embodiments, the driving frequency may be approximately 250 MHz.

In various embodiments, the driving frequency may be the operating frequency of any other electro-optical, acoustic-optical, or optical component configured to correct the phase error between the high-power portion of the first beam and the high-power portion of the second beam.

In various embodiments, the phase noise between the low power portion of the first beam and the low power portion of the second beam (as for example is present in the third mixer output after the detection phase noise is suppressed) may be used to either correct the phase noise on the high-power portion of the first beam or on the high-power portion of the second beam.

In various embodiments, the phase noise may be added to or subtracted from any of the high-power portion of the first or second beam to remove the phase noise difference between the two. In various embodiments, the AOM 610 may be used to add or subtract the phase noise to the high-power portion of the first beam using the third mixer output signal 608 (as shown in the example embodiment illustrated by FIG. 6). In various embodiments, another AOM 611 may be used to add or subtract the phase noise to the high-power portion of the second beam using the third mixer output signal 608. In various embodiments, an RF switch may be used to control inputting the third mixer output signal 608 to the AOM 611.

In various embodiments, when the phase noise is subtracted from any of the high-power portions of the first or second beams (for example using the corresponding AOM) to remove the phase difference between the two, a lower sideband of the third mixer output signal 608 is used. In various embodiments, when using this approach and for the third mixer output signal 608 to be approximately at the driving frequency of the corresponding AOM, the third signal generator 602 may be configured to generate a third signal generator output 604 having a frequency approximately equal to the offset frequency plus a driving frequency value (as for example described above). In this example, when choosing a lower sideband of the third mixer output signal 608, the offset frequency and the phase noise present at the modulated first signal generator output 534 are subtracted from the frequency of the third signal generator output 604 and the phase noise present in the third mixer output signal 608 has a negative value with respect to its carrier and will be subtracted from any of the high-power portions of the first or second beams to correct the phase noise between the two.

In various embodiments, when the phase noise is added to any of the high-power portions of the first or second beams (for example using the corresponding AOM) to remove the phase difference between the two, an upper sideband of the third mixer output signal 608 is used. In various embodiments, when using this approach and for the third mixer output signal 608 to be approximately at the driving frequency of the corresponding AOM, the third signal generator 602 may be configured to generate a third signal generator output 604 having a frequency approximately equal to the driving frequency value subtracted by the offset frequency. In this example, when choosing an upper sideband of the third mixer output signal 608, the offset frequency and the phase noise present at the modulated first signal generator output 534 are added to the frequency of the third signal generator output 604 and the phase noise present in the third mixer output signal 608 has a positive value with respect to its carrier and will be added to any of the high-power portions of the first or second beams to correct the phase noise between the two.

In various embodiments, a filter at the output of the third mixer 606 may be used to select the upper or lower sideband to remain on the third mixer output signal 608.

In various embodiments, the laser system 600 includes a third mixer 606 configured to mix the third signal generator output 604 with the modulated first signal generator output 534 after the detection noise suppression (with reference to FIG. 5) to generate a third mixer output signal 608. In various embodiments, the acoustic optical modulator (AOM) 610 configured to correct the phase error between the high-power portion of the first beam and the high-power portion of the second beam by modulating the high-power portion of the first beam using the third mixer output signal 608.

In various embodiments, the laser system 600 includes a radio frequency (RF) switch 612. The RF switch 612 may be electronically coupled to the third mixer and the acoustic optical modulator. In various embodiments, the RF switch 612 is configured to switch on or off the modulation by the AOM 610 using the third mixer output signal. In various embodiments, the RF switch 612 is configured to switch on or off the electronic coupling of the third mixer 606 with the AOM 610.

In various embodiments, the high-power portion of the first beam and the high-power portion of the second beam entangle qubits in a quantum computer, for example the quantum computer 110 with reference to FIG. 2. In various embodiments, the high-power portion of the first beam and the high-power portion of the second beam provide a first and second laser sources in a coherent heterodyne optical system, for example in any of quantum systems, optical communications systems, optical transmission and/or detection systems, optical signal processing, light detection and ranging (lidar) systems, optical coherent tomography, etc.

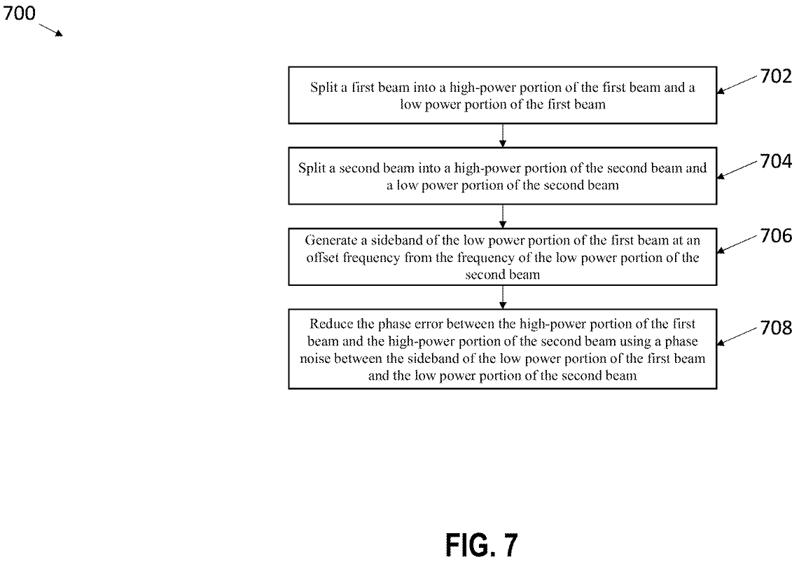

Referring now to FIG. 7 a schematic diagram illustrating various steps of a method 700 for reducing phase noise between optical beams is provided in accordance with various embodiments of the present disclosure. In various embodiments, any of the components and/or laser systems illustrated in FIGS. 1-6 may be used to perform various steps of the method 700. In various embodiments, a controller and/or processor, for example with reference to FIG. 2 or FIGS. 11-12 below may be used to perform various steps of the method 700.

In various embodiments, at step 702, the method 700 splits a first beam into a high-power portion of the first beam and a low power portion of the first beam. In various embodiments, the method 700 uses the first beam splitter 302 to split the first beam 304 into a high-power portion of the first beam 306 and a low power portion of the first beam 308.

In various embodiments, at step 704, the method 700 splits a second beam into a high-power portion of the second beam and a low power portion of the second beam. In various embodiments, the method 700 uses the second beam splitter 312 to split the second beam 314 into a high-power portion 316 of the second beam and a low power portion 318 of the second beam. In various embodiments, a frequency of the first beam is shifted with respect to a frequency of the second beam.

In various embodiments, at step 706, the method 700 generates a sideband of the low power portion of the first beam at an offset frequency from the frequency of the low power portion of the second beam. In various embodiments, the method 700 uses the EOM 322 to generate the sideband 324 of the low power portion of the first beam at the offset frequency by modulating the low power portion of the second beam. In various embodiments, at the offset frequency is less than the frequency shift between the first and second beams.

In various embodiments, at step 708, the method 700 reduces the phase error between the high-power portion of the first beam and the high-power portion of the second beam using a phase noise between the sideband of the low power portion of the first beam and the low power portion of the second beam. In various embodiments, the method 700 generates a heterodyne beam 328 by combining the sideband of the low power portion of the first beam and the low power portion of the second beam using the combiner 326. In various embodiments, the method 700 detects the heterodyne beam using the photodetector 344 to generate a heterodyne signal 346. In various embodiments, the method 700 reduces and/or removes a detection noise from the heterodyne signal using any of the systems and/or techniques described herein to generate a quiet heterodyne signal. In various embodiments, the quiet heterodyne signal includes the phase noise between the high-power portion of the first and second beams and/or includes information on the phase noise between the high-power portion of the first and second beams. In various embodiments, the method 700 uses the quiet heterodyne signal to reduce the phase noise between the high-power portion of the first and second beams using any of the systems and/or techniques described herein.

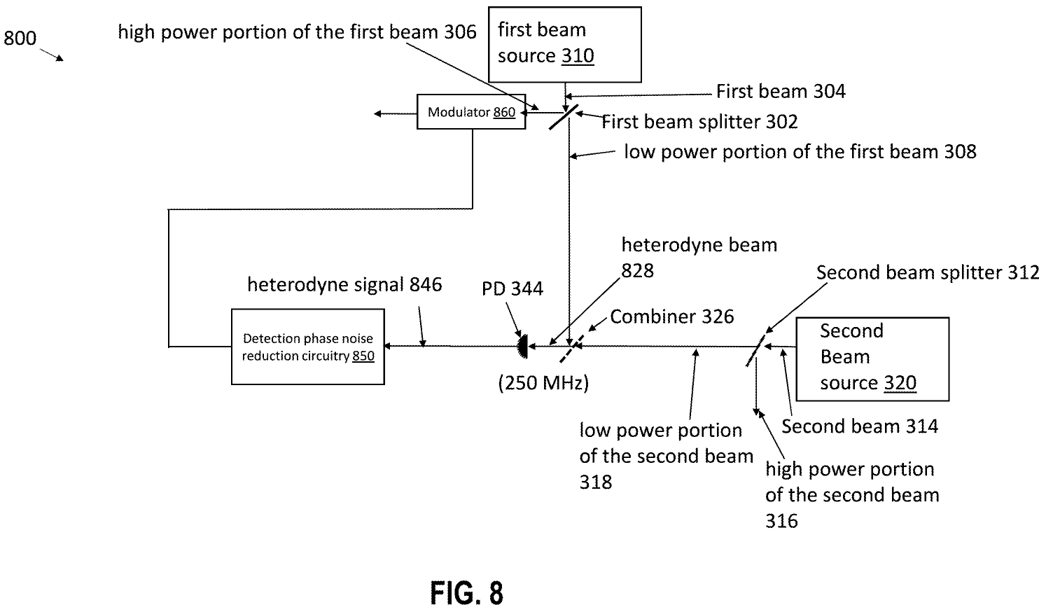

Referring now to FIG. 8 a schematic diagram illustrating various aspects of a laser system 800 is provided in accordance with various embodiments of the present disclosure. In various embodiments, the laser system 800 includes the first beam splitter 302 configured to split the first beam 304 into the high-power portion 306 of the first beam and a low power portion 308 of the first beam. In various embodiments, the laser system 800 includes a second beam splitter 312 configured to split the second beam 314 into a high-power portion 316 of the second beam and a low power portion 318 of the second beam. In various embodiments, the frequency of the first beam is shifted with respect to a frequency of the second beam.

In various embodiments, the laser system 800 includes a combiner 326 configured to combine the low power portion 308 of the first beam and the low power portion 318 of the second beam to generate a heterodyne beam 828. In various embodiments, a heterodyne frequency of the heterodyne beam 828 is indicative of and/or includes a phase noise between the low power portion of the first beam and the low power portion of the second beam. In various embodiments, heterodyne frequency of the heterodyne beam 828 includes information on the phase noise between the low power portion of the first beam and the low power portion of the second beam.

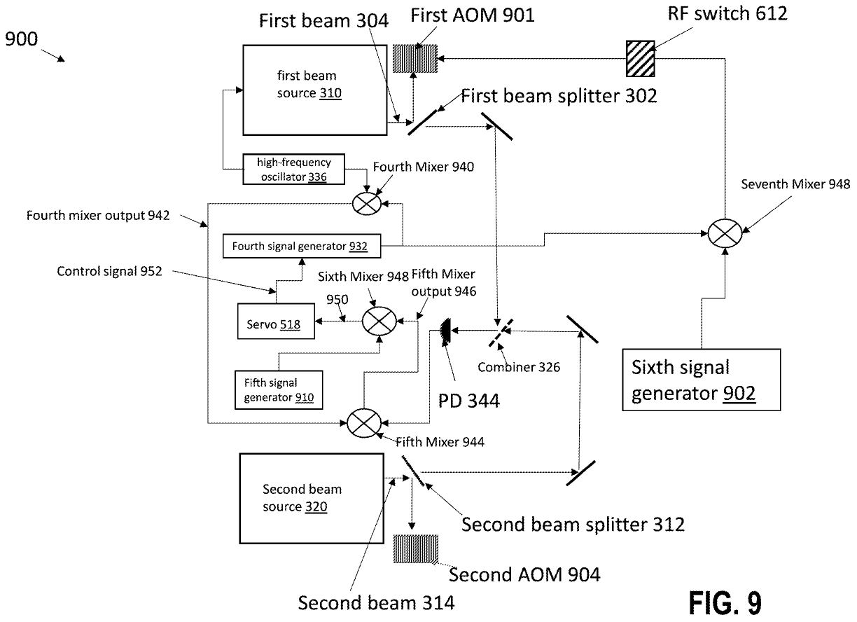

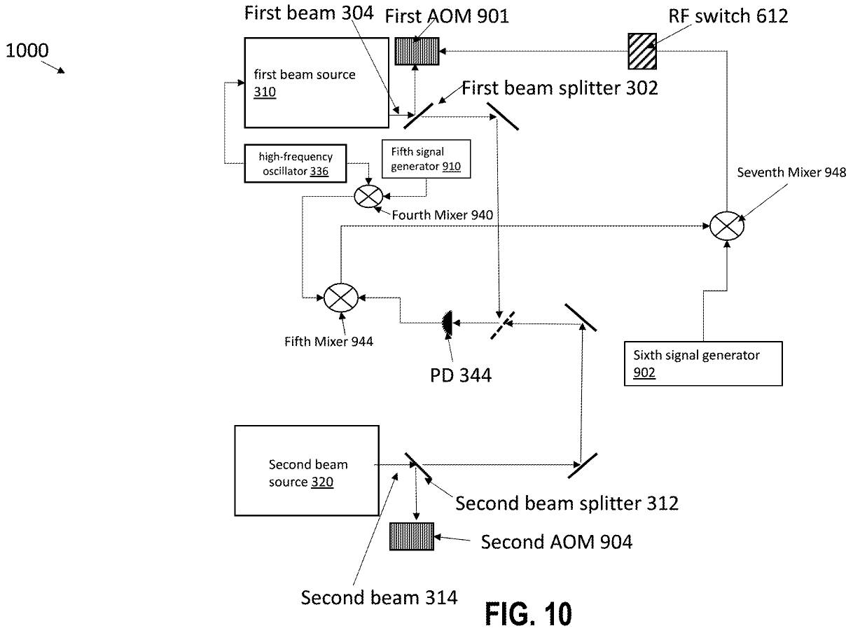

In various embodiments, the phase noise between the low power portion of the first beam and the low power portion of the second beam is used to reduce a phase error between the high-power portion of the first beam and the high-power portion of the second beam for example using any of the systems and/or techniques described with respect to FIGS. 9-10.

In various embodiments, the laser system 800 includes a photodetector (PD) 344. In various embodiments, the PD 344 is configured to detect the heterodyne beam 828 having the heterodyne frequency and generate a detected heterodyne signal 846 by detecting the heterodyne beam. In various embodiments, the detected heterodyne signal includes the phase noise between the low power portion of the first beam and the low power portion of the second beam, and a detection phase noise generated by the photodetector in detecting the heterodyne beam.

In various embodiments, the laser system 800 includes a detection phase noise reduction circuitry 850. In various embodiments, the detection phase noise reduction circuitry 850 is configured to reduce the detection phase noise in the detected heterodyne signal. In various embodiments, the detection phase noise reduction circuitry 850 is configured to suppress the detection phase noise in the detected heterodyne signal.

In various embodiments, the detection phase noise reduction circuitry 850 is configured to use the phase noise between the low power portion of the first beam and the low power portion of the second beam to correct the phase noise in the high power portion of the first beam (as for example illustrated by FIG. 8) and/or in the high power portion of the second beam.

In example embodiments, the laser system 800 is and/or includes a phase lock loop configured to suppress the detection phase noise in an output of the photodetector. In various embodiments, the detection phase noise reduction circuitry (e.g., a phase lock loop) is configured to generate a signal for reducing the phase difference between the high-power portion of the first beam and the high-power portion of the second beam. In various embodiments, the detection phase noise is reduced and/or removed in the signal generated by the detection phase noise reduction circuitry (e.g., a phase lock loop). In various embodiments, the detection phase noise reduction circuitry (e.g., a phase lock loop) generates a signal that modulates any of the high-power portion of the first or second beams to remove the phase noise between the high-power portion of the first and second beams.

In various embodiments, the laser system 800 includes a modulator 860 configured to correct the phase error between the high-power portion of the first beam and the high-power portion of the second beam using the detected heterodyne signal and the reduction of the detection phase noise.

Referring now to FIG. 9 a schematic diagram illustrating various aspects of a laser system 900 is provided in accordance with various embodiments of the present disclosure.

In various embodiments, the laser system 900 includes a fourth signal generator 932 configured to generate a fourth signal generator output. In various embodiments, the fourth signal generator is a voltage-controlled signal generator. For example, the frequency of the fourth signal generator output may be controlled using an input voltage to the fourth signal generator.

In various embodiments, the laser system 900 includes a fourth mixer 940 and a high-frequency oscillator 336. In various embodiments, the fourth mixer 940 is configured to mix the fourth signal generator output with a high frequency oscillator output to generate a fourth mixer output signal.

In various embodiments, the laser system 900 includes a fifth mixer 944. The fifth mixer 944 may be configured to mix the fourth mixer output signal with the detected heterodyne signal 846 (with reference to FIG. 8) to generate a fifth mixer output signal. In various embodiments, the laser system 900 includes a fifth signal generator 910 configured to generate a fifth signal generator output. In various embodiments, the laser system 900 includes a sixth mixer 948 configured to mix the fifth signal generator output with the fifth mixer output signal to generate a sixth mixer output signal.

In various embodiments, the laser system 900 includes a servo 518. In various embodiments, the servo 518 is a servo loop filter. In various embodiments, the servo 518 is configured to receive the sixth mixer output signal and generate a control signal using the sixth mixer output signal. In various embodiments, the control signal frequency modulates the fourth signal generator 932 to generate a modulated fourth signal generator output.

In various embodiments, the laser system 900 includes a sixth signal generator 902 configured to generate a sixth signal generator output. In various embodiments, the laser system 900 includes a seventh mixer 948 configured to mix the modulated fourth signal generator output with the sixth signal generator output to generate a seventh mixer output signal.

In various embodiments, the laser system 900 includes a first acoustic optical modulator 901 configured to correct the phase error between the high-power portion of the first beam and the high-power portion of the second beam by modulating the high-power portion of the first beam using the seventh mixer output signal. In various embodiments, a frequency of the seventh mixer output signal is approximately equal to an operating frequency of an acoustic-optical modulator.

In various embodiments, the laser system 900 includes a second acoustic optical modulator 904 configured to correct the phase error between the high-power portion of the first beam and the high-power portion of the second beam by modulating the high-power portion of the second beam using the seventh mixer output signal.

In various embodiments, the laser system 900 includes a radio frequency switch 612 electronically coupled to the seventh mixer and the acoustic optical modulator, the radio frequency switch configured to switch on or off the modulation by the acoustic optical modulator using the seventh mixer output signal.

In various embodiments, by locking the fourth signal generator 932 to the control signal, the adjustment in the phase of the high-power portion of the first or second signal (using first or second AOM) is not impacted by the detection phase noise.

In various embodiments, the detection phase noise reduction circuitry 850 (with reference to FIG. 8) comprises any of the high-frequency oscillator 336, the fourth mixer 940, the fourth signal generator 932, the servo 518, the sixth mixer 948, the fifth mixer 944, the fifth signal generator 910, the seventh mixer 948 and/or the RF switch 612 as for example illustrated in the schematic diagram of FIG. 9.

In various embodiments, the laser system 900 may or may not include the folding mirrors for directing the beams and/or may have folding mirrors and/or other redirecting components in various other arrangements as for example previously described.

In example embodiments, the first and second beams are ultraviolet beams with frequencies near 800 THz. In example embodiments, the frequency of the first beam is shifted by approximately 12640 MHz with respect to the frequency of the second beam. In example embodiments, the fourth signal generator 932 may generate an output at a frequency of approximately 160 MHz. In example embodiments, the high-frequency oscillator 336 may produce an output at approximately 12640 MHz. In example embodiments, the fifth signal generator may produce an output at a frequency of approximately 160 MHz. In example embodiments, a frequency of the fourth mixer output signal may be approximately 12480 MHZ.

In various embodiments, the phase noise between the low power portion of the first beam and the low power portion of the second beam (as for example is present in the seventh mixer output) may be used to either correct the phase noise on the high-power portion of the first beam or on the high-power portion of the second beam.

In various embodiments, the phase noise may be added to or subtracted from any of the high-power portion of the first or second beam to remove the phase noise difference between the two. In various embodiments, the first AOM 901 may be used to add or subtract the phase noise to the high-power portion of the first beam using the seventh mixer output signal (as shown in the example embodiment illustrated by FIGS. 9 and 10). In various embodiments, a second AOM 904 may be used to add or subtract the phase noise to the high-power portion of the second beam using the seventh mixer output signal. In various embodiments, an RF switch may be used to control inputting the seventh mixer output signal to the AOM 904.

In various embodiments, when the phase noise is subtracted from any of the high-power portions of the first or second beams (for example using the corresponding AOM) to remove the phase difference between the two, a lower sideband of the seventh mixer output signal is used. In various embodiments, when using this approach and for the seventh mixer output signal to be approximately at the driving frequency of the corresponding AOM, the sixth signal generator 902 may be configured to generate a sixth signal generator output having a frequency approximately equal to the frequency of the fourth signal generator 932 plus a driving frequency value. In this example, when choosing a lower sideband of the seventh mixer output signal, the frequency of the fourth signal generator 932 and the phase noise present at the fourth signal generator 932 output signal are subtracted from the frequency of the sixth signal generator output and the phase noise present in the seventh mixer output signal has a negative value with respect to its carrier and will be subtracted from any of the high-power portions of the first or second beams to correct the phase noise between the two.

In various embodiments, when the phase noise is added to any of the high-power portions of the first or second beams (for example using the corresponding AOM) to remove the phase difference between the two, an upper sideband of the seventh mixer output signal is used. In various embodiments, when using this approach and for the seventh mixer output signal to be approximately at the driving frequency of the corresponding AOM, the sixth signal generator may be configured to generate a sixth signal generator output having a frequency approximately equal to the driving frequency value subtracted by the frequency of the fourth signal generator 932. In this example, when choosing an upper sideband of the seventh mixer output signal, the frequency of the fourth signal generator 932 and the phase noise present at the fourth signal generator 932 output signal are added to the frequency of the sixth signal generator output and the phase noise present in the seventh mixer output signal has a positive value with respect to its carrier and will be added to any of the high-power portions of the first or second beams to correct the phase noise between the two.

In various embodiments, a filter at the output of the seventh mixer may be used to select the upper or lower sideband to remain on the seventh mixer output signal.

For example, when the driving frequency for the operation of the first or second AOMs is approximately 200 MHz and an output frequency of the fourth signal generator 932 is approximately 160 MHz, a frequency of the sixth signal generator is approximately 360 MHz or 40 MHz corresponding to the example embodiments described above.

Referring now to FIG. 10 a schematic diagram illustrating various aspects of a laser system 1000 is provided in accordance with various embodiments of the present disclosure. In various embodiments, the laser system 1000 includes a fifth signal generator 944 configured to generate a fifth signal generator output. In various embodiments, the laser system 1000 includes a fourth mixer configured to mix the fifth signal generator output with an output of a high-frequency oscillator 336 to generate a fourth mixer output signal.

In various embodiments, the laser system 1000 includes a fifth mixer 944 configured to mix the fourth mixer output signal with the detected heterodyne signal 846 (with reference to FIG. 8) to generate a fifth mixer output signal. In various embodiments, the laser system 1000 includes a sixth signal generator 902 configured to generate a sixth signal generator output. In various embodiments, the laser system 1000 includes a seventh mixer 948 configured to mix the fifth mixer output signal with the sixth signal generator output to generate a seventh mixer output signal.

In various embodiments, the laser system 1000 includes a first acoustic optical modulator 901 configured to correct the phase error between the high-power portion of the first beam and the high-power portion of the second beam by modulating the high-power portion of the first beam using the seventh mixer output signal. In various embodiments, the laser system 1000 includes a second acoustic optical modulator 904 configured to correct the phase error between the high-power portion of the first beam and the high-power portion of the second beam by modulating the high-power portion of the second beam using the seventh mixer output signal.

In various embodiments, the laser system 1000 includes a radio frequency switch 612 electronically coupled to the seventh mixer and the acoustic optical modulator. In various embodiments, the radio frequency switch is configured to switch on or off the modulation by the acoustic optical modulator using the seventh mixer output signal.

In various embodiments, a resonant photodetector may be used. In various embodiments, the fifth mixer output signal is mixed with the sixth signal generator to generate the seventh mixer output signal for controlling any of the first or second AOMs.

In various embodiments, the detection phase noise reduction circuitry 850 (with reference to FIG. 8) comprises any of the high-frequency oscillator 336, the fourth mixer 940, the fifth mixer 944, the fifth signal generator 910, the seventh mixer 948 and/or the RF switch 612 as for example illustrated in the schematic diagram of FIG. 10.

In various embodiments, the laser system 1000 may or may not include the folding mirrors for directing the beams and/or may have folding mirrors and/or other redirecting components in various other arrangements as for example previously described.

In example embodiments, the frequency of the first beam is shifted by approximately 12640 MHz with respect to the frequency of the second beam. In example embodiments, the high-frequency oscillator 336 may produce an output at approximately 12640 MHz. In example embodiments, the fifth signal generator may produce an output at a frequency of approximately 160 MHz. In example embodiments, a frequency of the fourth mixer output signal may be approximately 12480 MHZ.

In various embodiments, the phase noise between the low power portion of the first beam and the low power portion of the second beam (as for example is present in the seventh mixer output) may be used to either correct the phase noise on the high-power portion of the first beam or on the high-power portion of the second beam.

In various embodiments, the phase noise may be added to or subtracted from any of the high-power portion of the first or second beam to remove the phase noise difference between the two. In various embodiments, the first AOM 901 may be used to add or subtract the phase noise to the high-power portion of the first beam using the seventh mixer output signal (as shown in the example embodiment illustrated by FIGS. 9 and 10). In various embodiments, a second AOM 904 may be used to add or subtract the phase noise to the high-power portion of the second beam using the seventh mixer output signal. In various embodiments, an RF switch may be used to control inputting the seventh mixer output signal to the AOM 904.

In various embodiments, when the phase noise is subtracted from any of the high-power portions of the first or second beams (for example using the corresponding AOM) to remove the phase difference between the two, a lower sideband of the seventh mixer output signal is used. In various embodiments, when using this approach and for the seventh mixer output signal to be approximately at the driving frequency of the corresponding AOM, the sixth signal generator 902 may be configured to generate a sixth signal generator output having a frequency approximately equal to the frequency of the fifth mixer output plus a driving frequency value. In this example, when choosing a lower sideband of the seventh mixer output signal, the frequency of the fifth mixer output and the phase noise present at the fifth mixer output signal are subtracted from the frequency of the sixth signal generator output and the phase noise present in the seventh mixer output signal has a negative value with respect to its carrier and will be subtracted from any of the high-power portions of the first or second beams to correct the phase noise between the two.

In various embodiments, when the phase noise is added to any of the high-power portions of the first or second beams (for example using the corresponding AOM) to remove the phase difference between the two, an upper sideband of the seventh mixer output signal is used. In various embodiments, when using this approach and for the seventh mixer output signal to be approximately at the driving frequency of the corresponding AOM, the sixth signal generator may be configured to generate a sixth signal generator output having a frequency approximately equal to the driving frequency value subtracted by the frequency of the fifth mixer output. In this example, when choosing an upper sideband of the seventh mixer output signal, the frequency of the fifth mixer output and the phase noise present at the fifth mixer output signal are added to the frequency of the sixth signal generator output and the phase noise present in the seventh mixer output signal has a positive value with respect to its carrier and will be added to any of the high-power portions of the first or second beams to correct the phase noise between the two.

In various embodiments, a filter at the output of the seventh mixer may be used to select the upper or lower sideband to remain on the seventh mixer output signal.

For example, when the driving frequency for the operation of the first or second AOMs is approximately 200 MHz and an output frequency of the fifth mixer output is approximately 160 MHz, a frequency of the sixth signal generator is approximately 360 MHz or 40 MHz corresponding to the example embodiments described above.

In various embodiments, the high-power portion of the first beam and the high-power portion of the second beam in any of the laser systems presented above, for example laser systems 900 or 1000, entangle qubits in a quantum computer. In various embodiments, the high-power portion of the first beam and the high-power portion of the second beam in any of the laser systems presented above, for example laser systems 900 or 1000, provide a first and second laser sources in a coherent heterodyne optical system. In various embodiments, the coherent heterodyne optical system comprises any of an optical communications system or a light detection and ranging (lidar) system.

### Exemplary Controller

In various embodiments, a quantum computer 110 further comprises a controller 1130 configured to control various elements of the quantum computer 110. In various embodiments, a controller 1130 may be configured to cause a quantum computer 110 to perform various operations (e.g., computing operations such as gate operations, cooling operations, transport operations, qubit interaction operations, qubit measure operations, leakage suppression operations, and/or the like). For example, the controller 1130 may be configured to cause manipulation sources 64A, 64B to provide manipulation signals to quantum objects trapped within the trap 50. For example, the controller 1130 may be configured to cause the bichromatic laser system 100 to provide one or more gate signals to one or more quantum objects trapped within the trap 50 so as to enact, for example, one or more quantum gates. In various embodiments, the controller 1130 may be configured to control a cryogenic system and/or vacuum system controlling the temperature and pressure within the cryogenic and/or vacuum chamber 40, manipulation sources 64, and/or other systems controlling the environmental conditions (e.g., temperature, humidity, pressure, and/or the like) within the cryogenic and/or vacuum chamber 40 and/or configured to manipulate and/or cause a controlled evolution of quantum states of one or more quantum within the trap 50.

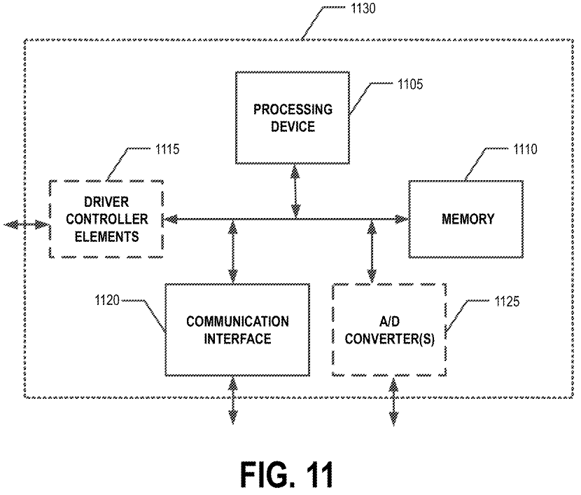

As shown in FIG. 11, in various embodiments, the controller 1130 may comprise various controller elements including processing elements 1105, memory 1110, driver controller elements 1115, a communication interface 1120, analog-digital converter elements 1125, and/or the like. For example, the processing elements 1105 may comprise programmable logic devices (CPLDs), microprocessors, coprocessing entities, application-specific instruction-set processors (ASIPs), integrated circuits, application specific integrated circuits (ASICs), field programmable gate arrays (FPGAs), programmable logic arrays (PLAs), hardware accelerators, other processing devices and/or circuitry, and/or the like, and/or controllers. The term circuitry may refer to an entirely hardware embodiment or a combination of hardware and computer program products. In an example embodiment, the processing element 1105 of the controller 1130 comprises a clock and/or is in communication with a clock.

For example, the memory 1110 may comprise non-transitory memory such as volatile and/or non-volatile memory storage such as one or more of as hard disks, ROM, PROM, EPROM, EEPROM, flash memory, MMCs, SD memory cards, Memory Sticks, CBRAM, PRAM, FORAM, RRAM, SONOS, racetrack memory, RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. In various embodiments, the memory 1110 may store qubit records corresponding the qubits of quantum computer (e.g., in a qubit record data store, qubit record database, qubit record table, and/or the like), a calibration table, an executable queue, computer program code (e.g., in a one or more computer languages, specialized controller language(s), and/or the like), and/or the like. In an example embodiment, execution of at least a portion of the computer program code stored in the memory 1110 (e.g., by a processing element 1105) causes the controller 1130 to perform one or more steps, operations, processes, procedures and/or the like described herein for tracking the phase of an quantum object within an quantum system and causing the adjustment of the phase of one or more manipulation sources and/or signal(s) generated thereby.

In various embodiments, the driver controller elements 1115 may include one or more drivers and/or controller elements each configured to control one or more drivers. In various embodiments, the driver controller elements 1115 may comprise drivers and/or driver controllers. For example, the driver controllers may be configured to cause one or more corresponding drivers to be operated in accordance with executable instructions, commands, and/or the like scheduled and executed by the controller 1130 (e.g., by the processing element 1105). In various embodiments, the driver controller elements 1115 may enable the controller 1130 to operate the bichromatic laser system 100, manipulation sources 64, operate vacuum and/or cryogenic systems, and/or the like. In various embodiments, the drivers may be laser drivers; microwave drivers; vacuum component drivers; cryogenic and/or vacuum system component drivers; current drivers, and/or the like. For example, the drivers and/or driver controllers may be configured to cause a magnetic field generation device (e.g., comprising circuitry coupled to a voltage source (e.g., a current driver or voltage driver), permanent magnet(s), and/or a combination thereof) to generate a magnetic field having a particular direction and magnitude at one or more positions of the trap 50. In various embodiments, the controller 1130 comprises means for communicating and/or receiving signals from one or more optical receiver components such as cameras, MEMs cameras, CCD cameras, photodiodes, photomultiplier tubes, and/or the like. For example, the controller 1130 may comprise one or more analog-digital converter elements 1125 configured to receive signals from one or more optical receiver components, calibration sensors, and/or the like.

In various embodiments, the controller 1130 may comprise a communication interface 1120 for interfacing and/or communicating with a computing entity 1210. For example, the controller 1130 may comprise a communication interface 1120 for receiving executable instructions, command sets, and/or the like from the computing entity 1210 and providing output received from the quantum computer 110 (e.g., from an optical collection system) and/or the result of a processing the output to the computing entity 1210. In various embodiments, the computing entity 1210 and the controller 1130 may communicate via a direct wired and/or wireless connection and/or one or more wired and/or wireless networks 20.

### Exemplary Computing Entity

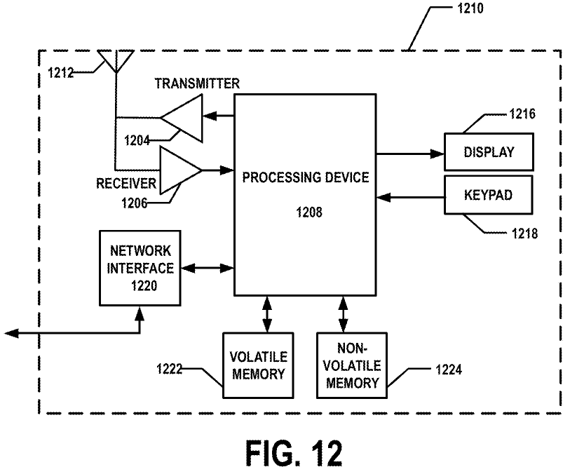

FIG. 12 provides an illustrative schematic representative of an example computing entity 1210 that can be used in conjunction with embodiments of the present invention. In various embodiments, a computing entity 1210 is configured to allow a user to provide input to the quantum computer 110 (e.g., via a user interface of the computing entity 1210) and receive, display, analyze, and/or the like output from the quantum computer 110. For example, a user may operate a computing entity 1210 to generate and/or program a quantum algorithm and/or quantum circuit (e.g., that includes a D-state AC-Stark shift gate) that may be provided such that the controller 1130 may receive the quantum algorithm and/or quantum circuit and cause the quantum computer 110 to perform the quantum algorithm and/or quantum circuit.

As shown in FIG. 12, a computing entity 1210 can include an antenna 1212, a transmitter 1204 (e.g., radio), a receiver 1206 (e.g., radio), and a processing element 1208 that provides signals to and receives signals from the transmitter 1204 and receiver 1206, respectively. The signals provided to and received from the transmitter 1204 and the receiver 1206, respectively, may include signaling information/data in accordance with an air interface standard of applicable wireless systems to communicate with various entities, such as a controller 1130, other computing entities 1210, and/or the like. In this regard, the computing entity 1210 may be capable of operating with one or more air interface standards, communication protocols, modulation types, and access types. For example, the computing entity 1210 may be configured to receive and/or provide communications using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 1210 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra wideband (UWB), infrared (IR) protocols, near field communication (NFC) protocols, Wibrec, Bluetooth protocols, wireless universal serial bus (USB) protocols, and/or any other wireless protocol. The computing entity 1210 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

Via these communication standards and protocols, the computing entity 1210 can communicate with various other entities using concepts such as Unstructured Supplementary Service information/data (USSD), Short Message Service (SMS), Multimedia Messaging Service (MMS), Dual-Tone Multi-Frequency Signaling (DTMF), and/or Subscriber Identity Module Dialer (SIM dialer). The computing entity 1210 can also download changes, add-ons, and updates, for instance, to its firmware, software (e.g., including executable instructions, applications, program modules), and operating system.

The computing entity 1210 may also comprise a user interface device comprising one or more user input/output interfaces (e.g., a display 1216 and/or speaker/speaker driver coupled to a processing element 1208 and a touch screen, keyboard, mouse, and/or microphone coupled to a processing element 1208). For instance, the user output interface may be configured to provide an application, browser, user interface, interface, dashboard, screen, webpage, page, and/or similar words used herein interchangeably executing on and/or accessible via the computing entity 1210 to cause display or audible presentation of information/data and for interaction therewith via one or more user input interfaces. The user input interface can comprise any of a number of devices allowing the computing entity 1210 to receive data, such as a keypad 1218 (hard or soft), a touch display, voice/speech or motion interfaces, scanners, readers, or other input device. In embodiments including a keypad 1218, the keypad 1218 can include (or cause display of) the conventional numeric (0-9) and related keys (#, *), and other keys used for operating the computing entity 1210 and may include a full set of alphabetic keys or set of keys that may be activated to provide a full set of alphanumeric keys. In addition to providing input, the user input interface can be used, for example, to activate or deactivate certain functions, such as screen savers and/or sleep modes. Through such inputs the computing entity 1210 can collect information/data, user interaction/input, and/or the like.

The computing entity 1210 can also include volatile storage or memory 1222 and/or non-volatile storage or memory 1224, which can be embedded and/or may be removable. For instance, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database management system entities, data, applications, programs, program modules, scripts, source code, object code, byte code, compiled code, interpreted code, machine code, executable instructions, and/or the like to implement the functions of the computing entity 1210.

### CONCLUSION

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

1. A laser system comprising:
a first beam splitter configured to split a first beam into a high-power portion of the first beam and a low power portion of the first beam;
a second beam splitter configured to split a second beam into a high-power portion of the second beam and a low power portion of the second beam, wherein a frequency of the first beam is shifted with respect to a frequency of the second beam; and
an electro-optical modulator configured to generate a sideband of the low power portion of the first beam at an offset frequency from the frequency of the low power portion of the second beam,
wherein a phase noise between the sideband of the low power portion of the first beam and the low power portion of the second beam is used to reduce a phase error between the high-power portion of the first beam and the high-power portion of the second beam.

2. The laser system of claim 1, wherein the offset frequency between the sideband of the low power portion of the first beam and the low power portion of the second beam is less than a frequency difference between the first beam and the second beam.

3. The laser system of claim 2 comprising an oscillator configured to generate an oscillation signal having an oscillation frequency equal to a frequency difference between the frequency of the low power portion of the first beam and the sideband of the low power portion of the first beam, wherein the electro-optical modulator is configured to use the oscillation signal to generate the sideband of the low power portion of the first beam.

4. The laser system of claim 3, wherein the oscillator comprising:
a first signal generator configured to generate a first signal generator output wherein a frequency of the first signal generator output is equal to the offset frequency;
a high-frequency oscillator configured to generate a high-frequency signal output having a high frequency related to half of the shift between the frequency of the first beam with respect to the frequency of the second beam; and
a first mixer configured to mix the first signal generator output with the high-frequency signal output to generate the oscillation signal.

5. The laser system of claim 4, comprising a combiner configured to combine the sideband of the low power portion of the first beam and the low power portion of the second beam to generate a heterodyne beam, wherein a heterodyne frequency of the heterodyne beam is indicative of the phase noise between the sideband of the low power portion of the first beam and the low power portion of the second beam.

6. The laser system of claim 5, comprising:
a photodetector configured to:
detect the heterodyne beam; and
generate a detected heterodyne signal using the detection of the heterodyne beam, wherein the detected heterodyne signal comprises:
the phase noise between the sideband of the low power portion of the first beam and the low power portion of the second beam; and
a detection phase noise generated by the photodetector in detecting the heterodyne beam.

7. The laser system of claim 6, comprising a phase lock loop configured to suppress the detection phase noise in the detected heterodyne signal to generate a quiet detected heterodyne signal on an output of the photodetector, wherein the quiet detected heterodyne signal comprises the phase noise between the sideband of the low power portion of the first beam and the low power portion of the second beam.

8. The laser system of claim 6, comprising:
a second signal generator configured to generate a second signal generator output wherein a frequency of the second signal generator output is equal to the offset frequency; and
a second mixer configured to mix the detected heterodyne signal with the second signal generator output to generate an error signal indicative of the detection phase noise.

9. The laser system of claim 8, comprising a servo loop filter configured to receive the error signal and generate a control signal using the error signal, wherein the control signal frequency modulates the first signal generator such that a modulated first signal generator output comprises the detection phase noise.

10. The laser system of claim 9, wherein the first mixer is configured to mix the modulated first signal generator output with the high-frequency signal output such that the detection phase noise in the detected heterodyne signal is suppressed and a quiet detected heterodyne signal on an output of the photodetector is generated, wherein the quiet detected heterodyne signal comprises the phase noise between the sideband of the low power portion of the first beam and the low power portion of the second beam.

11. The laser system of claim 9, further comprising:
a third signal generator configured to generate a third signal generator output having a frequency approximately equal to the offset frequency plus a driving frequency value;
a third mixer configured to mix the third signal generator output with the modulated first signal generator output to generate a third mixer output signal;
an acoustic optical modulator configured to correct the phase error between the high-power portion of the first beam and the high-power portion of the second beam by modulating the high-power portion of the first beam using the third mixer output signal; and
a radio frequency switch electronically coupled to the third mixer and the acoustic optical modulator, the radio frequency switch configured to switch on or off the modulation by the acoustic optical modulator using the third mixer output signal.

12. The laser system of claim 1, wherein the high-power portion of the first beam and the high-power portion of the second beam do at least one of (a) entangle qubits in a quantum computer or (b) provide a first and second laser sources in a coherent heterodyne optical system.

13. The laser system of claim 1, wherein the high-power portion of the first beam and the high-power portion of the second beam provide first and second laser sources in a coherent heterodyne optical system, the coherent heterodyne optical system comprises at least one of (a) an optical communications system or (b) a light detection and ranging (lidar) system.

14. A laser system comprising:
a first beam splitter configured to split the first beam into a high-power portion of the first beam and a low power portion of the first beam;
a second beam splitter configured to split the second beam into a high-power portion of the second beam and a low power portion of the second beam, wherein a frequency of the first beam is shifted with respect to a frequency of the second beam; and
a combiner configured to combine the low power portion of the first beam and the low power portion of the second beam to generate a heterodyne beam, wherein a heterodyne frequency of the heterodyne beam is indicative of a phase noise between the low power portion of the first beam and the low power portion of the second beam, and the phase noise between the low power portion of the first beam and the low power portion of the second beam is used to reduce a phase error between the high-power portion of the first beam and the high-power portion of the second beam.

15. The laser system of claim 14, comprising:
a photodetector configured to:
detect the heterodyne beam having the heterodyne frequency; and
generate a detected heterodyne signal by detecting the heterodyne beam, wherein the detected heterodyne signal comprises:
the phase noise between the low power portion of the first beam and the low power portion of the second beam; and
a detection phase noise generated by the photodetector in detecting the heterodyne beam;
a detection phase noise reduction circuitry configured to reduce the detection phase noise in the detected heterodyne signal; and
a modulator configured to correct the phase error between the high-power portion of the first beam and the high-power portion of the second beam using the detected heterodyne signal and the reduction of the detection phase noise.

16. The laser system of claim 14, comprising:
a fourth signal generator configured to generate a fourth signal generator output, wherein the fourth signal generator is a voltage-controlled signal generator;
a fourth mixer configured to mix the fourth signal generator output with a high frequency oscillator output to generate a fourth mixer output signal;
a fifth mixer configured to mix the fourth mixer output signal with the detected heterodyne signal to generate a fifth mixer output signal;
a fifth signal generator configured to generate a fifth signal generator output;
a sixth mixer configured to mix the fifth signal generator output with the fifth mixer output signal to generate a sixth mixer output signal;
a servo loop filter configured to receive the sixth mixer output signal and generate a control signal using the sixth mixer output signal, wherein the control signal frequency modulates the fourth signal generator to generate a modulated fourth signal generator output;
a sixth signal generator configured to generate a sixth signal generator output;
a seventh mixer configured to mix the modulated fourth signal generator output with the sixth signal generator output to generate a seventh mixer output signal;
a first acoustic optical modulator configured to correct the phase error between the high-power portion of the first beam and the high-power portion of the second beam by modulating the high-power portion of the first beam using the seventh mixer output signal or a second acoustic optical modulator configured to correct the phase error between the high-power portion of the first beam and the high-power portion of the second beam by modulating the high-power portion of the second beam using the seventh mixer output signal; and
a radio frequency switch electronically coupled to the seventh mixer and the acoustic optical modulator, the radio frequency switch configured to switch on or off the modulation by the acoustic optical modulator using the seventh mixer output signal.

17. The laser system of claim 14, comprising:
a fifth signal generator configured to generate a fifth signal generator output;
a fourth mixer configured to mix the fifth signal generator output with an output of a high-frequency oscillator to generate a fourth mixer output signal;
a fifth mixer configured to mix the fourth mixer output signal with the detected heterodyne signal to generate a fifth mixer output signal;
a sixth signal generator configured to generate a sixth signal generator output;
a seventh mixer configured to mix the fifth mixer output signal with the sixth signal generator output to generate a seventh mixer output signal;
a first acoustic optical modulator configured to correct the phase error between the high-power portion of the first beam and the high-power portion of the second beam by modulating the high-power portion of the first beam using the seventh mixer output signal or a second acoustic optical modulator configured to correct the phase error between the high-power portion of the first beam and the high-power portion of the second beam by modulating the high-power portion of the second beam using the seventh mixer output signal; and
a radio frequency switch electronically coupled to the seventh mixer and the acoustic optical modulator, the radio frequency switch configured to switch on or off the modulation by the acoustic optical modulator using the seventh mixer output signal.

18. The laser system of claim 14, wherein the high-power portion of the first beam and the high-power portion of the second beam are configured to perform at least one of (a) entangling qubits in a quantum computer or (b) providing first and second laser sources in a coherent heterodyne optical system.

19. The laser system of claim 14, wherein the high-power portion of the first beam and the high-power portion of the second beam are configured to provide first and second laser sources in a coherent heterodyne optical system and the coherent heterodyne optical system comprises any of an optical communications system or a light detection and ranging (lidar) system.

20. A method for reducing phase noise between optical beams, the method comprising:
splitting a first beam into a high-power portion of the first beam and a low power portion of the first beam;
splitting a second beam into a high-power portion of the second beam and a low power portion of the second beam, wherein a frequency of the first beam is shifted with respect to a frequency of the second beam;
generating a sideband of the low power portion of the first beam at an offset frequency from the frequency of the low power portion of the second beam; and
reducing the phase error between the high-power portion of the first beam and the high-power portion of the second beam using a phase noise between the sideband of the low power portion of the first beam and the low power portion of the second beam.
